(19) United States
(12) Patent Application Publication
(10) Pub. No.: US 2026/0354286 A1
(43) Pub. Date: Nov. 5, 2026

(54) FUSE EVENT SHIELDS FOR SEMICONDUCTOR PACKAGE PROTECTION

(71) Applicant: TEXAS INSTRUMENTS INCORPORATED, Dallas, TX (US)

(72) Inventor: Enis TUNCER, Dallas, TX (US)

(21) Appl. No.: 19/195,616

(22) Filed: Apr. 30, 2025

(51) Int. Cl. H10W 90/00; H10W 70/00; H10W 70/40; H10W 70/65; H10W 72/00; H10W 72/50; H10W 74/10

(52) U.S. Cl. CPC H10W 90/701; H10W 70/099; H10W 70/411; H10W 70/65; H10W 70/424; H10W 72/536; H10W 72/5363; H10W 72/5445; H10W 72/884; H10W 74/10; H10W 90/736; H10W 90/756

(57) ABSTRACT

In examples, a semiconductor package includes a die attach pad, a semiconductor die attached to the die attach pad, a conductive terminal physically separate from the die attach pad, a bond wire attached to the semiconductor die and to the conductive terminal, a structure extending over the bond wire, and a mold compound covering the die attach pad, the semiconductor die, the conductive terminal, the bond wire, and the structure.

### BACKGROUND

Semiconductor wafers are circular pieces of semiconductor material, such as silicon, that are used to manufacture semiconductor chips. Generally, complex manufacturing processes are used to form numerous integrated circuits on a single semiconductor wafer. The formation of such circuits on a semiconductor wafer is called fabrication. After semiconductor wafer fabrication, the semiconductor wafer is cut into multiple pieces, called semiconductor dies, with each semiconductor die containing one of the circuits. The cutting, or sawing, of the semiconductor wafer into individual semiconductor dies is called singulation. An individual semiconductor die may then be attached to a substrate or die attach pad. The resulting structure may be subsequently covered with a mold compound to produce a semiconductor package.

### SUMMARY

In examples, a semiconductor package includes a die attach pad, a semiconductor die attached to the die attach pad, a conductive terminal physically separate from the die attach pad, a bond wire attached to the semiconductor die and to the conductive terminal, a structure extending over the bond wire, and a mold compound covering the die attach pad, the semiconductor die, the conductive terminal, the bond wire, and the structure.

In examples, a method for operating a semiconductor package includes passing a current through a bond wire in the semiconductor package, where the current is sufficient to cause a fuse event in the bond wire, and the bond wire is not embedded in a semiconductor die of the semiconductor package. The method also includes using a structure located within the semiconductor package and extending over the bond wire to physically block the bond wire from rupturing a mold compound covering the bond wire during the fuse event.

### BRIEF DESCRIPTION OF THE DRAWINGS

FIG. 1A is a top-down view of a semiconductor package having a fuse event shield to protect the semiconductor package from fuse events, in accordance with various examples.

FIG. 1B is a profile view of a semiconductor package having a fuse event shield to protect the semiconductor package from fuse events, in accordance with various examples.

FIG. 1C is a profile view of a semiconductor package having a fuse event shield to protect the semiconductor package from fuse events, in accordance with various examples.

FIG. 1D is a perspective view of a semiconductor package having a fuse event shield to protect the semiconductor package from fuse events, in accordance with various examples.

FIG. 1E is a top-down view of a semiconductor package having a fuse event shield to protect the semiconductor package from fuse events, in accordance with various examples.

FIG. 1F is a profile view of a semiconductor package having a fuse event shield to protect the semiconductor package from fuse events, in accordance with various examples.

FIG. 1G is a profile view of a semiconductor package having a fuse event shield to protect the semiconductor package from fuse events, in accordance with various examples.

FIG. 1H is a perspective view of a semiconductor package having a fuse event shield to protect the semiconductor package from fuse events, in accordance with various examples.

FIG. 2A is a top-down view of a semiconductor package having a fuse event shield to protect the semiconductor package from fuse events, in accordance with various examples.

FIG. 2B is a profile view of a semiconductor package having a fuse event shield to protect the semiconductor package from fuse events, in accordance with various examples.

FIG. 2C is a profile view of a semiconductor package having a fuse event shield to protect the semiconductor package from fuse events, in accordance with various examples.

FIG. 2D is a perspective view of a semiconductor package having a fuse event shield to protect the semiconductor package from fuse events, in accordance with various examples.

FIG. 3A is a top-down view of a semiconductor package having a fuse event shield to protect the semiconductor package from fuse events, in accordance with various examples.

FIG. 3B is a profile view of a semiconductor package having a fuse event shield to protect the semiconductor package from fuse events, in accordance with various examples.

FIG. 3C is a profile view of a semiconductor package having a fuse event shield to protect the semiconductor package from fuse events, in accordance with various examples.

FIG. 3D is a perspective view of a semiconductor package having a fuse event shield to protect the semiconductor package from fuse events, in accordance with various examples.

FIG. 4 is a flow diagram of a method for operating a semiconductor package having a fuse event shield to protect the semiconductor package from fuse events, in accordance with various examples.

FIG. 5 is a block diagram of an electronic device including a semiconductor package having a fuse event shield to protect the semiconductor package from fuse events, in accordance with various examples.

### DETAILED DESCRIPTION

When an overcurrent condition occurs in a semiconductor package bond wire, resistive heating increases as current density exceeds the bond wire capacity, leading to thermal runaway. As a result, the bond wire temperature rises rapidly, causing metallurgical changes that further accelerate failure. As the temperature reaches the bond wire melting point, a localized molten region forms, expanding under Joule heating and surface tension effects until mechanical integrity is lost. The molten segment rapidly vaporizes, leading to an abrupt open-circuit condition. At the moment of rupture, stored elastic energy in the remaining segments of the bond wire is released, causing a rapid displacement of the severed ends of the bond wire. The sudden mechanical acceleration of the fractured bond wire sections imparts forces onto the surrounding mold compound. These forces can induce delamination at the mold compound-bond wire interface, initiate microcracking, or cause larger-scale fractures in the mold compound, depending on the trajectory of the bond wire.

This description presents various examples of a semiconductor package having a fuse event shield (FES) to protect the semiconductor package during fuse events. (As used herein, a “fuse” comprises a protective electrical device (e.g., a bond wire) that contains a metal conductor capable of melting and thus breaking the circuit of which the fuse is a part when excessive current flows, thus preventing damage to the apparatus in which the fuse is present.) More particularly, the FES, which comprises any suitable structure capable of withstanding the fuse event bond wire displacement forces described above and remaining intact, extends over one or more bond wires that are susceptible to fuse events due to overcurrent conditions. The FES is positioned above (e.g., within 250 microns of) the bond wire as measured in the vertical direction, thereby mitigating damage to the mold compound that may result from a fuse event. Specifically, the FES minimizes bond wire displacement that would otherwise occur due to a fuse event. When the FES contains bond wire displacement in this manner, the bond wire is prevented from significantly damaging the mold compound and/or other semiconductor package components. Additionally, the conductive FES helps dissipate heat generated by the fuse event, further preventing heat-related damage to structures surrounding the FES. In examples, the bond wire susceptible to fuse events is not a structure built into the semiconductor die and therefore is not part of the semiconductor die. Rather, the bond wire may attach to or extend over the semiconductor die, such as through the mold compound of the semiconductor package. The FES may include bond wires, clips, ribbon bonds, and various other suitable structures.

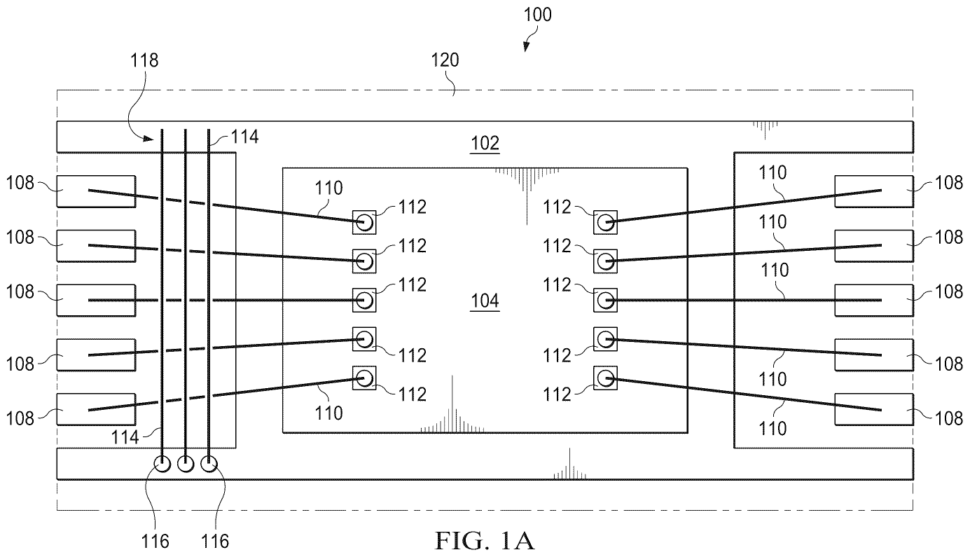

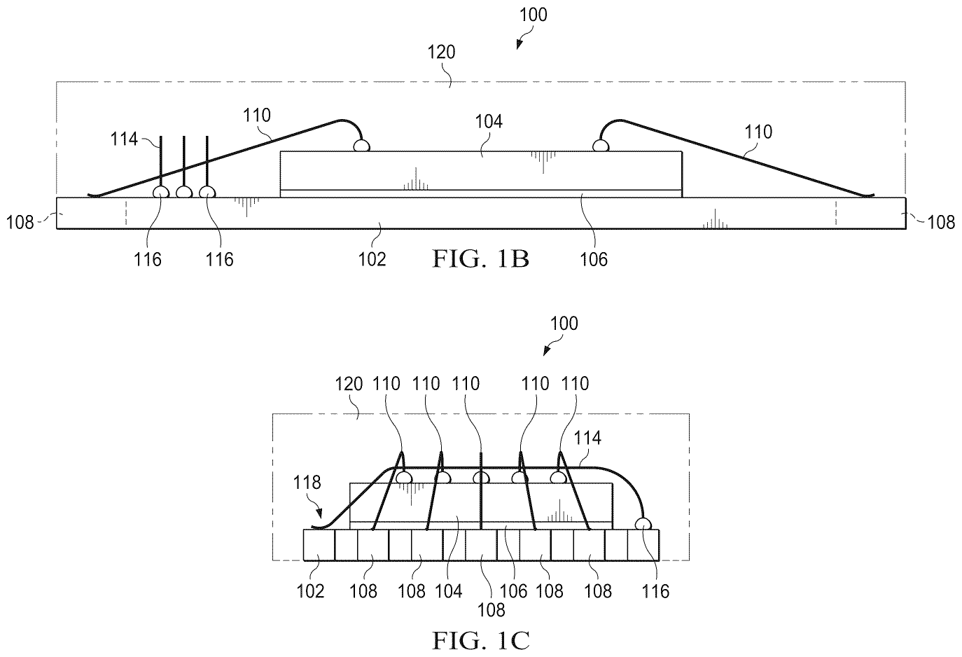

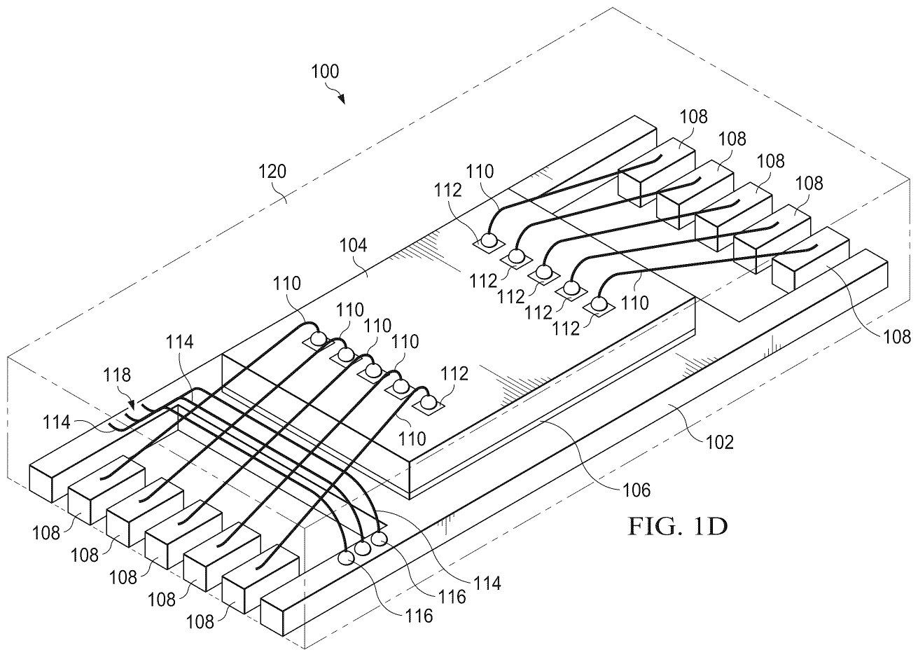

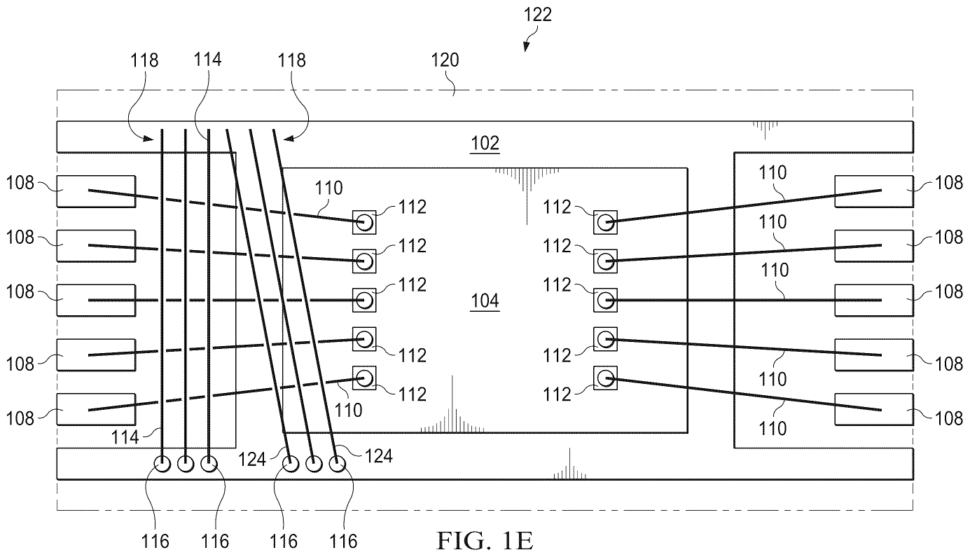

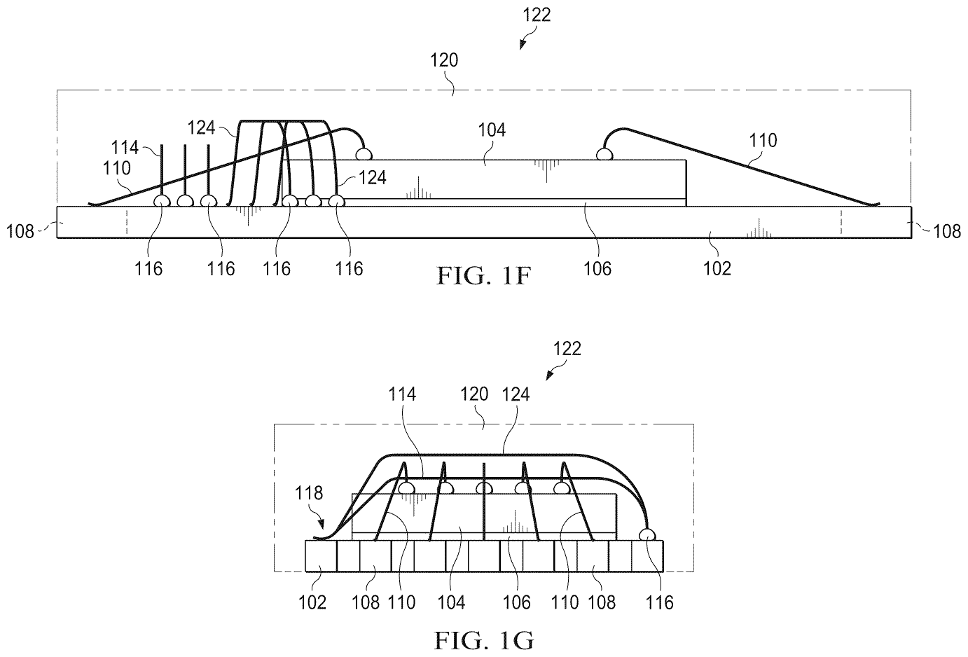

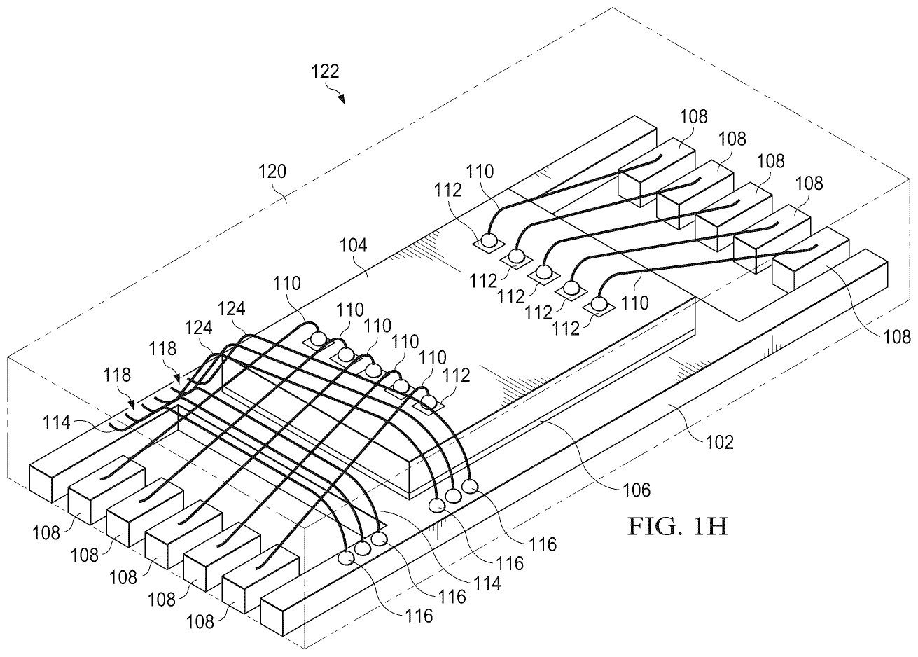

FIGS. 1A-1D are top-down, profile, profile, and perspective views of a semiconductor package having a fuse event shield to protect the semiconductor package from fuse events, in accordance with various examples. In particular, FIGS. 1A-1D depict a semiconductor package 100 including a die attach pad 102, a semiconductor die 104 (and more specifically, a non-device side of the semiconductor die 104) attached to the die attach pad 102 by die attach material 106, and conductive terminals 108. Collectively, the die attach pad 102 and the conductive terminals 108 may be referred to as a portion of a lead frame. Bond wires 110 are attached to the semiconductor die 104 (e.g., to bond pads 112 on a device side of the semiconductor die 104 in which an integrated circuit is formed) and to the conductive terminals 108. In examples, the bond wires 110 are attached to the semiconductor die 104 using ball bonds, and the bond wires 110 are attached to the conductive terminals 108 by stitch bonds, although the scope of this disclosure is not limited to any particular type of bond. In some examples, the semiconductor package 100 includes a single bond wire 110, and in other examples, the semiconductor package 100 includes multiple bond wires 110. For consistency, the remainder of this description assumes that the semiconductor package 100 includes multiple bond wires 110. The bond wires 110 are not within the semiconductor die 104. Instead, the bond wires 110 extend outside the semiconductor die 104, such as through a mold compound 120 of the semiconductor package 100.

One or more of the bond wires 110 has a maximum current rating that is below a maximal current that the semiconductor die 104 is capable of providing. For example, one or more of the bond wires 110 may be capable of carrying a maximum of 10 mA, while the semiconductor die 104 may be capable of providing 1000 mA on those bond wires 110. Thus, these bond wires 110 are susceptible to overcurrent conditions that result in the explosive bond wire displacements and mold compound damage described in detail above.

The semiconductor package 100 also includes bond wires 114 that extend over some of the bond wires 110 (e.g., the bond wires 110 that are susceptible to fuse events). In the example shown in FIGS. 1A-1D, each of the bond wires 114 has opposing ends that are attached to the same electrical node (e.g., both ends of each bond wire 114 are attached to the die attach pad 102). For example, each bond wire 114 may be attached to one area of the die attach pad 102 by a ball bond 116, and each bond wire 114 may be attached to a different area of the die attach pad 102 by a stitch bond 118. Other types of bonds are contemplated and included in the scope of this disclosure. Although the bond wires 114 extend over some of the bond wires 110, such as the bond wires 110 that are susceptible to fuse events, the bond wires 114 may not extend over all of the bond wires 110, as not all bond wires 110 may be susceptible to fuse events. The same principle applies to the remaining examples described herein.

As described below, the bond wires 114 collectively operate as a FES, although the bond wires 114 also may be considered to be a group of individual FESs. Structures other than bond wires 114 also may be useful as a FES. Specifically, the FES may be any type of structure that is capable of preventing or containing damage to the mold compound 120 upon a fuse event that causes explosive displacement of the bond wires 110. Although multiple bond wires 114 are shown as being part of the FES, more or fewer bond wires 114 (or other structure(s)) may be used. The bond wires 114 have a pitch ranging from 50 microns to 350 microns, with a pitch above this range being disadvantageous because of inadequate heat dissipation through the bond wires 114 during a fuse event to prevent thermal damage, and with a pitch below this range being disadvantageous because undesirably thin bond wires 114 would need to be implemented to accommodate the pitch, which, in turn, results in weak bond wires 114 and an undesirably large number of bond wires 114.

As described, each bond wire 114 has opposing ends that are attached to the same electrical node, such as the die attach pad 102. Because both ends of each bond wire 114 are attached to the same electrical node, there is no voltage differential between the two ends of the bond wire 114, meaning that no current flows through the bond wire 114. Lack of such current flow prevents the bond wire 114 from experiencing a fuse event, thereby facilitating the structural integrity and longevity of the bond wire 114. Further, lack of such current flow prevents interference with currents that flow through the bond wires 110, thereby enabling the distance between the bond wires 110 and the bond wires 114 to be small (i.e., each of the bond wires 114 maintains a vertical clearance from each of the bond wires 110 ranging from 50 microns to 250 microns along the length of that bond wire 114). Larger gaps than this range result in an unacceptably large size of the semiconductor package 100. Smaller gaps than this range risk contact between the structures, such as during application of the mold compound 120.

In some examples, the bond wires 114 are capable of carrying current, meaning that the opposing ends of each bond wire 114 are attached to different electrical nodes within the semiconductor package 100. In such examples, each of the bond wires 114 is separated from each of the bond wires 110 by a vertical clearance of at least 250 microns along a length of that bond wire 114 to prevent interference between the bond wires 114 and the bond wires 110. Such examples provide additional functionality to the semiconductor package 100. In such examples, the melting point of each bond wire 114 exceeds the melting point of each bond wire 110 by at least 50 degrees Celsius, such that the overcurrent conditions that can trigger a fuse event in a bond wire 110 are not able to similarly trigger a fuse event in a bond wire 114. The maximal current rating of each bond wire 114 exceeds a maximal current that the semiconductor die 104 is capable of providing to that bond wire 114 by at least 500 mA. The diameter of each bond wire 114 ranges from 20 microns to 50 microns, with a diameter above this range being disadvantageous because the bond wires 114 become too rigid for bonding, and with a diameter below this range being disadvantageous because the mechanical strength of the bond wires 114 becomes too low to protect against fuse events.

A bond wire 114 is positioned near the segment of a bond wire 110 that is most likely to melt first during a fuse event, because the loose ends of that bond wire 110 that form at that segment will be most likely to explosively displace and cause damage to the mold compound 120. Thus, a bond wire 114 placed near those loose ends newly-formed during a fuse event will protect the mold compound 120 from damage. Accordingly, each bond wire 114 lies in a vertical plane that intersects at least one bond wire 110 within 500 microns of an end of that bond wire 110.

In a top-down view, the vertical plane in which a bond wire 114 lies must intersect with the vertical plane in which a corresponding bond wire 110 lies at an angle sufficiently close to 90 degrees to ensure the bond wire 114 effectively blocks the bond wire 110 from moving upward and damaging the mold compound 120 during a fuse event. If this angle is not sufficiently close to 90 degrees (e.g., the vertical planes are nearly parallel), the bond wire 110 may slip past the bond wire 114 instead of being restrained. Accordingly, these vertical planes intersect at an angle that is within 15 degrees of perpendicular (i.e., 90 degrees) in a top-down view.

As described, the bond wires 114 may constitute a single FES, or each of the bond wires 114 may be considered to be individual FESs. In some examples, a semiconductor package may include multiple FESs, with each FES including multiple bond wires, as FIGS. 1E-1H show. FIGS. 1E-1H are top-down, profile, profile, and perspective views of a semiconductor package having a fuse event shield to protect the semiconductor package from fuse events, in accordance with various examples. More specifically, FIGS. 1E-1H depict a semiconductor package 122 that is identical to the semiconductor package 100 of FIGS. 1A-1D, except that the semiconductor package 122 includes bond wires 124, which, like the bond wires 114, extend over the bond wires 110 and protect the mold compound 120 and other components of the semiconductor package 122 from damage due to explosive displacement of the bond wires 110 during a fuse event. The description provided above for the properties and the positioning of the bond wires 114, including the use of ball bonds 116 and stitch bonds 118, also applies to the bond wires 124 and thus is not repeated here. The bond wires 124 may be positioned between 5%-30% of the distance from the ball bonds of the bond wires 110 to the stitch bonds of the bond wires 110, and the bond wires 114 may be positioned between 65%-80% of the distance from the ball bonds of the bond wires 110 to the stitch bonds of the bond wires 110, thereby facilitating the likelihood that the bond wires 110 will be prevented from damaging the mold compound 120 during a fuse event.

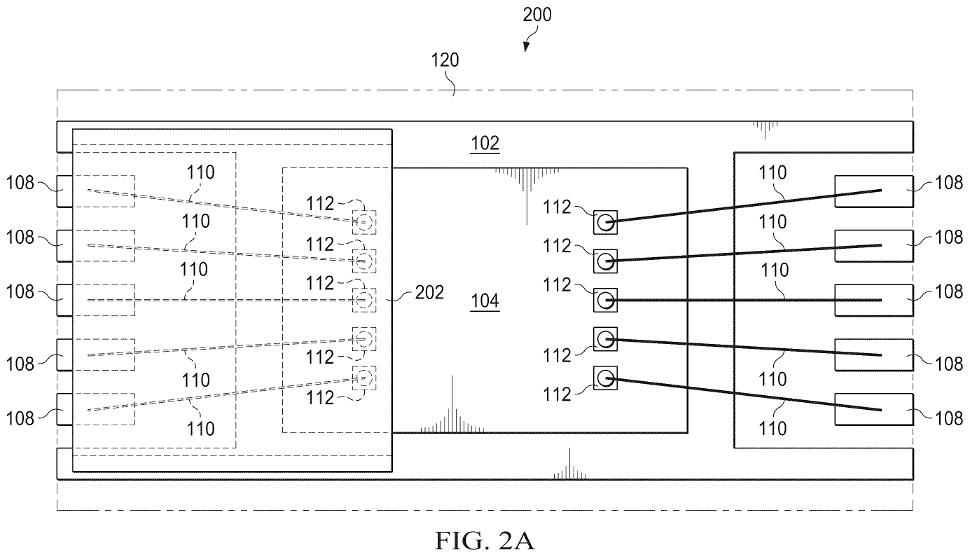

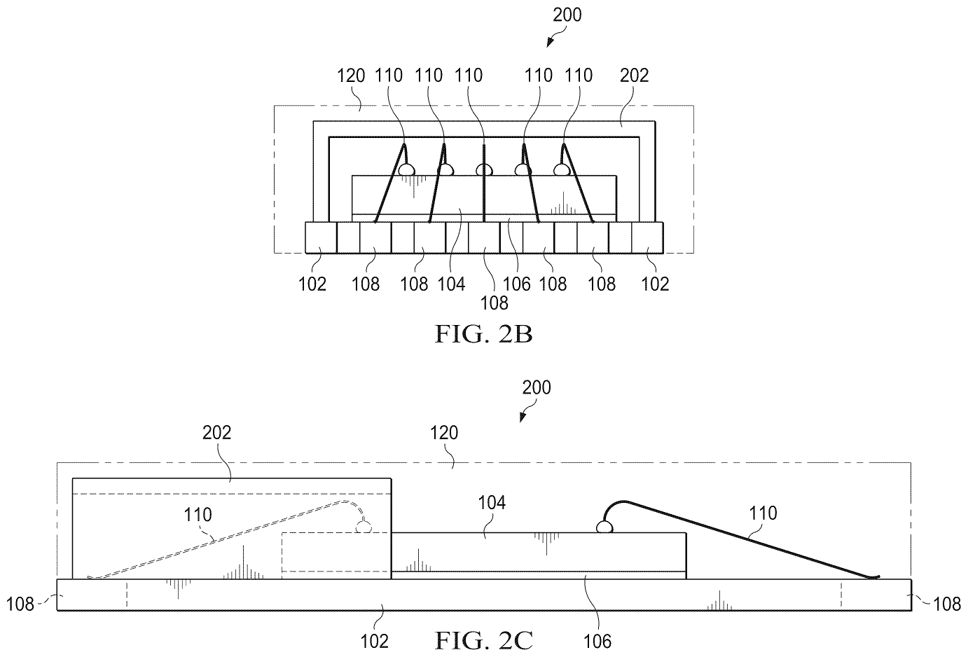

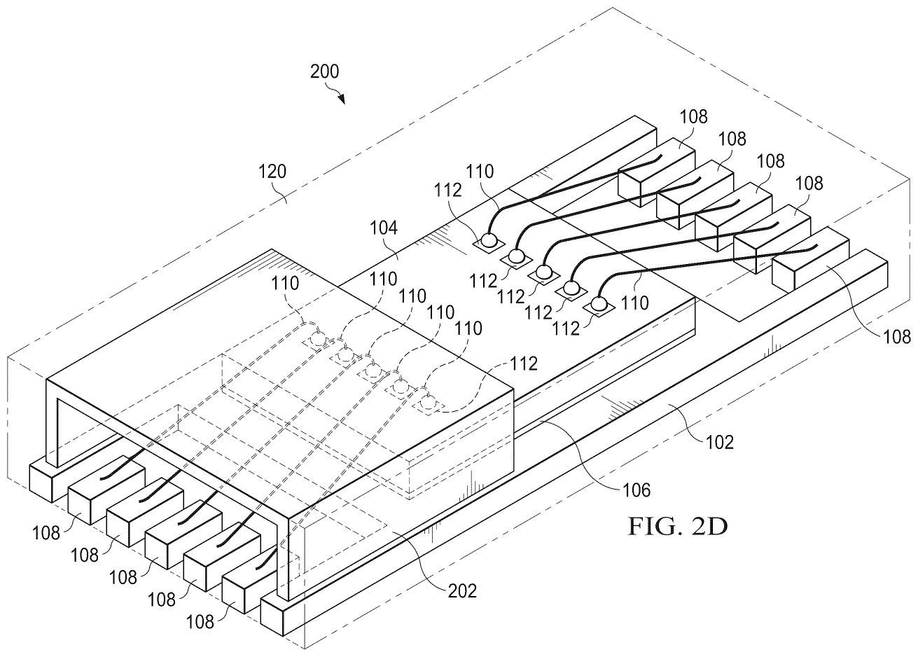

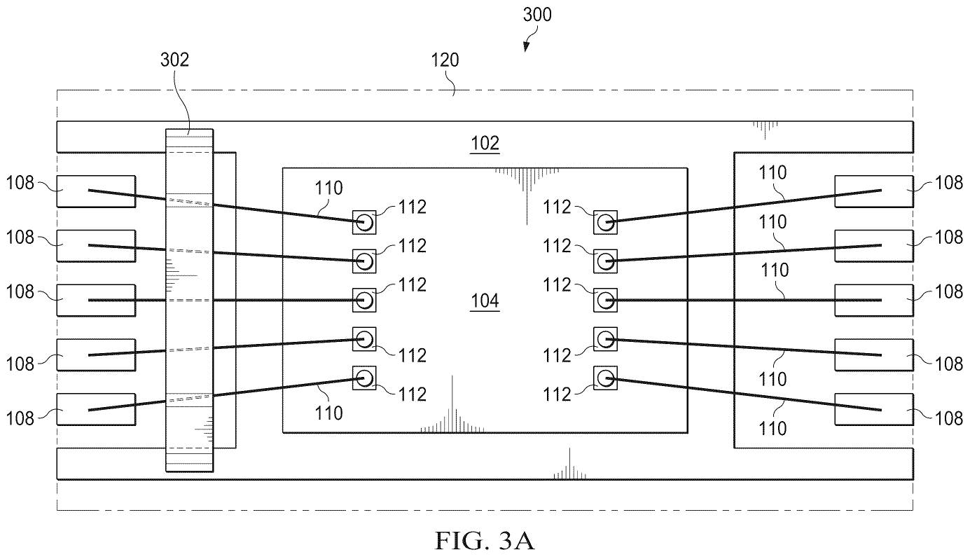

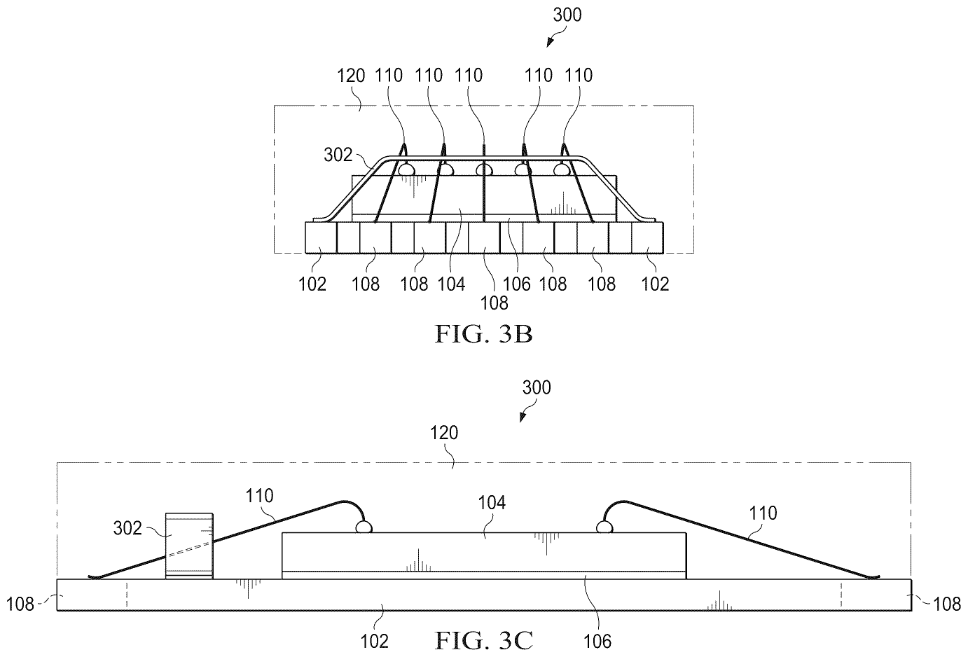

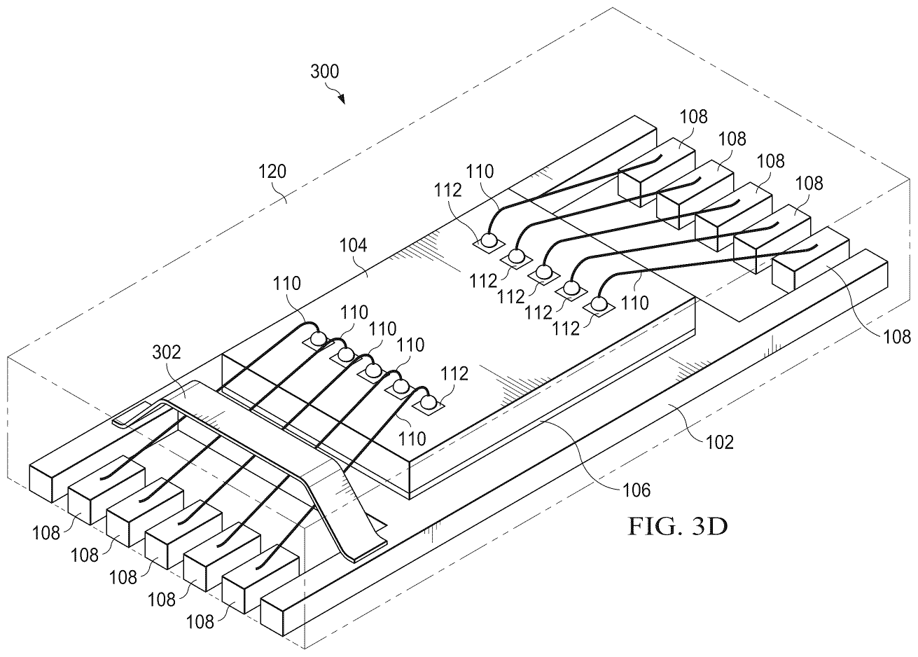

In some examples, structures other than bond wires 114, 124 may be useful as a FES. For instance, the FES may include structures such as clips (FIGS. 2A-2D) and ribbon bonds (FIGS. 3A-3D). FIGS. 2A-2D are top-down, profile, profile, and perspective views of a semiconductor package having a fuse event shield to protect the semiconductor package from fuse events, in accordance with various examples. More particularly, FIGS. 2A-2D depict a semiconductor package 200 that is identical to the semiconductor package 100 of FIGS. 1A-1D, except that a clip 202 is included as a FES in lieu of the bond wires 114. The clip 202 may include a variety of materials, such as copper, copper alloys (e.g., CuNiSi, CuCrZr), silver-plated copper, silver, aluminum, gold, liquid crystal polymer, polyether ether ketone, polyimide, ceramics (e.g., alumina, silicon nitride), and glass-filled epoxies. The clip 202 may be attached to two or more surfaces within the semiconductor package 200. These surfaces may be the same electrical node (e.g., the die attach pad 102) in the semiconductor package 200, or the surfaces may be different electrical nodes in the semiconductor package 200. If the clip 202 is conductive (e.g., a metal or alloy), coupling the clip 202 to multiple surfaces forming the same electrical node results in no current flow through the clip 202, as described above for some examples of the bond wire FESs. If the clip 202 is conductive, coupling the clip 202 to multiple surfaces forming different electrical nodes results in current flow through the clip 202, as described above for some examples of the bond wire FESs. If the clip 202 is non-conductive, the clip 202 does not carry current. Conductive clips 202 may be attached to respective surfaces by soldering, sintering, or another conductive adhesive, while non-conductive clips 202 may be attached to respective surfaces by adhesive bonding, mechanical clamping or press-fitting, or thermal interface material bonding, for example.

The clip 202 has a width, in the top-down view, that covers the bond wires 110 in their entireties, thus eliminating the possibility that the bond wires 110 could damage components of the semiconductor package 200 during a fuse event. The clip 202 maintains a vertical clearance over the bond wires 110 that is identical to the vertical clearance provided above for the bond wires 114. The clip 202 has a thickness of at least 25 microns, with a thickness below this threshold presenting a significant risk that the explosive displacement of the bond wire(s) 110 during a fuse event would fracture the clip 202, rendering the clip 202 ineffective to protect other parts of the semiconductor package 200 during the fuse event.

Structures other than bond wires and clips may be useful as FESs. For example, and as mentioned above, a ribbon bond may be useful as a FES. FIGS. 3A-3D are top-down, profile, profile, and perspective views of a semiconductor package having a fuse event shield to protect the semiconductor package from fuse events, in accordance with various examples. More particularly, FIGS. 3A-3D depict a semiconductor package 300 that is identical to the semiconductor package 100 of FIGS. 1A-1D, except that a ribbon bond 302 is included as a FES in lieu of the bond wires 114. The ribbon bond 302 may include any suitable material, such as gold, copper, or aluminum. Traditional ribbon bonding techniques may be useful to form the ribbon bond 302. For example, a wedge bonding tool may position ribbon material (e.g., fed and cut from a spool) over a first bond site and may form an ultrasonic or thermosonic wedge bond, may optionally form a loop or curve, and then may form a stitch or wedge bond on a second bond site, followed by a trimming process to remove excess ribbon material. The first and second bond sites may be, for example, the same electrical node (e.g., the die attach pad 102) or different electrical nodes within the semiconductor package 300. The width of the ribbon bond 302 from a top-down view ranges from 100 microns to 500 microns, with a width above this range being disadvantageous because of the high risk of mold compound voids below the ribbon bond 302, and with a width below this range being disadvantageous because the ribbon bond 302 will be inadequately mechanically robust to protect against a fuse event. The thickness of the ribbon bond 302 is the same as that of the clip 202 described above, and thus is not repeated here. The ribbon bond 302 (i.e., a lateral edge of the ribbon bond 302) is positioned within 500 microns of an end of a bond wire 110 in the top-down view. Although a single ribbon bond 302 is shown, in examples, multiple ribbon bonds 302 are included.

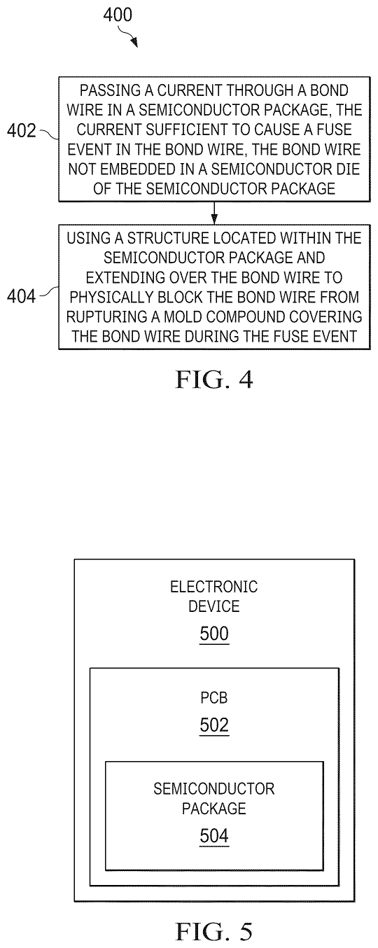

FIG. 4 is a flow diagram of a method 400 for operating a semiconductor package having a fuse event shield to protect the semiconductor package from fuse events, in accordance with various examples. The method 400 may be useful to operate any of the semiconductor packages described herein, such as the semiconductor packages 100, 122, 200, and 300. The method 400 includes passing a current through a bond wire in a semiconductor package (402). The current is sufficient to cause a fuse event in the bond wire (402). The bond wire is not embedded in a semiconductor die of the semiconductor package (402). For example, in the semiconductor package 100 of FIGS. 1A-1D, the semiconductor package 122 of FIGS. 1E-1H, the semiconductor package 200 of FIGS. 2A-2D, and/or the semiconductor package 300 of FIGS. 3A-3D, a current exceeding a maximal current rating of a bond wire 110 may flow through that bond wire 110.

The method 400 includes using a structure located within the semiconductor package and extending over the bond wire to physically block the bond wire from rupturing a mold compound covering the bond wire during the fuse event (404). For example, in the semiconductor package 100 of FIGS. 1A-1D, the bond wires 114 physically block the bond wire(s) 110 from rupturing the mold compound 120 during the fuse event. Similarly, in the semiconductor package 122 of FIGS. 1E-1H, the bond wires 114 and the bond wires 124 physically block the bond wire(s) 110 from rupturing the mold compound 120 during the fuse event. In the semiconductor package 200 of FIGS. 2A-2D, the clip 202 physically blocks the bond wire(s) 110 from rupturing the mold compound 120 during the fuse event. Likewise, in the semiconductor package 300 of FIGS. 3A-3D, the ribbon bond 302 physically blocks the bond wire(s) 110 from rupturing the mold compound 120 during the fuse event.

FIG. 5 is a block diagram of an electronic device including a semiconductor package having a fuse event shield to protect the semiconductor package from fuse events, in accordance with various examples. Specifically, an electronic device 500 includes a printed circuit board (PCB) 502 to which a semiconductor package 504 is attached. The semiconductor package 504 is representative of the semiconductor packages 100, 122, 200, and/or 300, for example. Examples of the electronic device 500 include an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system.

In this description, the term “attach” may cover connections, communications, or signal paths that enable a functional relationship consistent with this description. For example, if device A generates a signal to control device B to perform an action: (a) in a first example, device A is attached to device B by direct connection; or (b) in a second example, device A is attached to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a die attach pad;
a semiconductor die attached to the die attach pad;
a conductive terminal physically separate from the die attach pad;
a bond wire attached to the semiconductor die and to the conductive terminal;
a structure extending over the bond wire; and
a mold compound covering the die attach pad, the semiconductor die, the conductive terminal, the bond wire, and the structure.

2. The semiconductor package of claim 1, wherein the structure and the bond wire are separated by a gap ranging from 50 microns to 250 microns.

3. The semiconductor package of claim 1, wherein the structure comprises one of a clip and a ribbon bond.

4. The semiconductor package of claim 1, wherein the bond wire comprises a first bond wire, and the structure comprises a second bond wire.

5. The semiconductor package of claim 4, wherein a melting point of the second bond wire exceeds a melting point of the first bond wire.

6. The semiconductor package of claim 1, wherein the structure has first and second ends attached to the die attach pad.

7. The semiconductor package of claim 1, wherein the structure has first and second ends coupled to a same electrical node.

8. The semiconductor package of claim 1, wherein the bond wire is capable of operating as a fuse.

9. A semiconductor package, comprising:
a die attach pad;
a semiconductor die having a device side in which an integrated circuit is formed and a non-device side opposing the device side and attached to the die attach pad;
a conductive terminal physically separate from the die attach pad;
a first wire attached to the device side and to the conductive terminal, the first wire capable of operating as a fuse;
a second wire having first and second ends attached to the die attach pad and extending over the first wire; and
a mold compound covering the die attach pad, the semiconductor die, the conductive terminal, and the first and second wires.

10. The semiconductor package of claim 9, wherein a diameter of the second wire ranges from 20 to 50 microns.

11. The semiconductor package of claim 9, wherein the first wire is capable of operating as a fuse.

12. The semiconductor package of claim 9, further comprising a third wire having first and second ends attached to the die attach pad and extending over the first wire and over a portion of the semiconductor die.

13. The semiconductor package of claim 9, wherein the second wire maintains a clearance between 50 microns and 250 microns from the first wire along a length of the second wire.

14. The semiconductor package of claim 9, wherein a vertical plane in which the second wire lies intersects the first wire within 500 microns of an end of the first wire.

15. The semiconductor package of claim 9, wherein a first vertical plane coincident with the first wire is within 15 degrees of being perpendicular in a top-down view with a second vertical plane coincident with the second wire.

16. A method for operating a semiconductor package, comprising:
passing a current through a bond wire in the semiconductor package, the current sufficient to cause a fuse event in the bond wire, the bond wire not embedded in a semiconductor die of the semiconductor package; and
using a structure located within the semiconductor package and extending over the bond wire to physically block the bond wire from rupturing a mold compound covering the bond wire during the fuse event.

17. The method of claim 16, wherein the bond wire comprises a first bond wire, and wherein the structure comprises a second bond wire.

18. The method of claim 17, wherein a diameter of the second bond wire ranges from 20 to 50 microns.

19. The method of claim 16, wherein the structure comprises a clip.

20. The method of claim 16, wherein the structure has first and second ends attached to a die attach pad within the semiconductor package.
